(19) United States
(12) Patent Application Publication
(10) Pub. No.: US 2016/0095242 A1
(43) Pub. Date: Mar. 31, 2016

(54) ELECTRONIC DEVICE WITH DUST PROTECTING FUNCTION AND METHOD FOR FABRICATING ELECTRONIC DEVICE WITH DUST PROTECTING FUNCTION

(71) Applicant: 3R SEMICONDUCTOR TECHNOLOGY INC., HSINCHU (TW)

(72) Inventor: Dar-Chang Juang, Hsinchu City (TW)

(21) Appl. No.: 14/847,016

(22) Filed: Sep. 8, 2015

(30) Foreign Application Priority Data
Sep. 26, 2014 (TW) 103133631

(51) Int. Cl. H05K 5/03; G01L 19/14; H05K 3/30; H04R 1/02; H04R 31/00

(52) U.S. Cl. CPC H05K 5/03; H04R 1/02; H04R 31/00; H05K 3/30; G01L 19/14; H04R 2201/003

(57) ABSTRACT

The present invention provides an electronic device with dust protecting function and a method for fabricating the electronic device with dust protecting function. The electronic device comprises: a chamber structure and a first electronic element. The chamber structure comprises: a substrate; and a cap. The cap is connected to the substrate, and has a hole and a protruding part, wherein the protruding part protrudes toward inside of the chamber structure. The first electronic element is disposed in the chamber structure, wherein the protruding part is a block between the first electronic element and the hole of the cap.

### BACKGROUND OF THE INVENTION

1. Field of the Invention

The present invention relates to an electronic device and a method of fabricating an electronic device, and more particularly, to an electronic device with dust protecting function and a method of fabricating an electronic device with dust protecting function.

2. Description of the Prior Art

In general, a conventional Micro Electro Mechanical System (MEMS) microphone device has a hole on a cap of a package structure thereof, and a microphone chip in the package structure can receive outside sound signals via the hole. However, the outside dust also enters the package structure of the conventional MEMS microphone device via the hole and damage the microphone chip in the package structure.

### SUMMARY OF THE INVENTION

It is therefore one of the objectives of the present invention to provide an electronic device with dust protecting function and a method of fabricating an electronic device with dust protecting function, so as to solve the above problem.

In accordance with an embodiment of the present invention, an electronic device with dust protecting function is disclosed. The electronic device comprises: a chamber structure and a first electronic element. The chamber structure comprises a substrate and a cap connected to the substrate. The cap has a hole and a protruding part, and the protruding part protrudes toward inside of the chamber structure. The first electronic element is disposed in the chamber structure, wherein the protruding part is a block between the first electronic element and the hole of the cap.

In accordance with an embodiment of the present invention, a method of fabricating an electronic device with dust protecting function is disclosed. The method comprises: forming a chamber structure comprising a substrate and a cap, and the cap having a hole and a protruding part, wherein the protruding part protrudes toward inside of the chamber structure; and disposing a first electronic element in the chamber structure, wherein the protruding part is a block between the first electronic element and the hole of the cap.

Briefly summarized, in the electronic device (such as a MEMS microphone device or an atmospheric pressure measuring device) disclosed by the present invention, since the first electronic element (such as a MEMS microphone element or an atmospheric pressure measuring element) is blocked by the protruding part from the hole of the cap (i.e. the first electronic element is positioned in the dustproof zone of the chamber structure), the electronic device disclosed by the present invention can have extremely good dust protecting function to protect the first electronic element from the interference and impact of dust.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a simplified cross-sectional diagram of an electronic device 100 with dust protecting function in accordance with a first embodiment of the present invention.

FIG. 2 shows a simplified top-view diagram of the electronic device in FIG. 1.

FIG. 3 is a first exemplary flowchart showing a method of fabricating an electronic device with the dust protecting function in accordance with the electronic device in FIG. 1.

FIG. 4 shows a simplified cross-sectional diagram of an electronic device with dust protecting function in accordance with a second embodiment of the present invention.

FIG. 5 shows a simplified top-view diagram of the electronic device in FIG. 4.

FIG. 6 is a second exemplary flowchart showing a method of fabricating an electronic device with the dust protecting function in accordance with the electronic device in FIG. 4.

### DETAILED DESCRIPTION

Certain terms are used throughout the following description and the claims to refer to particular system components. As one skilled in the art will appreciate, manufacturers may refer to a component by different names. This document does not intend to distinguish between components that differ in name but not function. In the following discussion and in the claims, the terms “include”, “including”, “comprise”, and “comprising” are used in an open-ended fashion, and thus should be interpreted to mean “including, but not limited to . . . ”. The terms “couple” and “coupled” are intended to mean either an indirect or a direct electrical connection. Thus, if a first device couples to a second device, that connection may be through a direct electrical connection, or through an indirect electrical connection via other devices and connections.

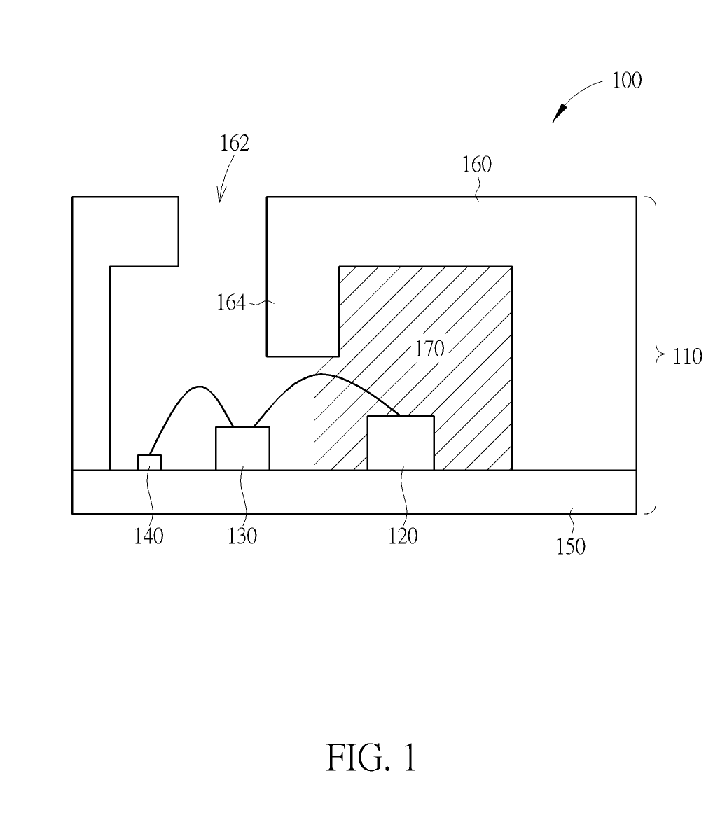

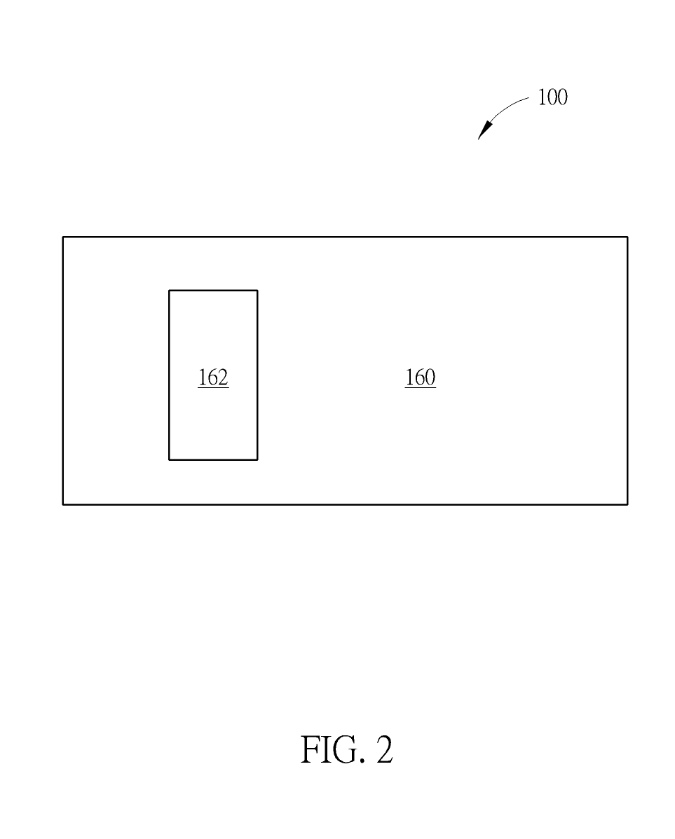

Please refer to FIG. 1 and FIG. 2. FIG. 1 shows a simplified cross-sectional diagram of an electronic device 100 with dust protecting function in accordance with a first embodiment of the present invention, and FIG. 2 shows a simplified top-view diagram of the electronic device 100, wherein the electronic device 100 can be a Micro Electro Mechanical System (MEMS) microphone device or an atmospheric pressure measuring device. The electronic device 100 comprises: a chamber structure 110 a first electronic element 120, a second electronic element 130, and a connecting pad 140, wherein the chamber structure 110 can be a package structure, the first electronic element 120 can be a MEMS microphone element or an atmospheric pressure measuring, and the second electronic element 130 can be an application-specific integrated circuit (ASIC). The chamber structure 110 comprises a substrate 150 and a cap 160, wherein the substrate 150 can be a printed circuit board (PCB) and material of the cap 160 can be metal or plastics. The cap 160 is connected to the substrate 150, and the cap 160 has a hole 162 and a protruding part 164. The present invention can use a punching process to form the hole 162 and the protruding part 164 in the same time, wherein the protruding part 164 protrudes toward inside of the chamber structure 110. Please note that the above embodiment is only for an illustrative purpose and is not meant to be a limitation of the present invention. For example, if there are other processes capable of forming the hole 162 and the protruding part 164 under different design requirements, the present invention also can use the other processes to form the hole 162 and the protruding part 164 on the cap 160.

In addition, the first electronic element 120 is disposed in the chamber structure 110 and disposed on the substrate 150. The second electronic element 130 is coupled to the first electronic element 120, and disposed in the chamber structure 110 and on the substrate 150. The connecting pad 140 is coupled to the second electronic element 130, and disposed in the chamber structure 110 and disposed on the substrate 150, wherein the protruding part 164 is a block between the first electronic element 120 and the hole 162 of the cap 160. In this way, the first electronic element 120 is positioned in a dustproof zone 170. Since the present invention can use the punching process to form the hole 162 and the protruding part 164 in the same time, the present invention can make the electronic device 100 (such as a MEMS microphone device or an atmospheric pressure measuring device) have dust protecting function to protect the first electronic element 120 (such as a MEMS microphone element or an atmospheric pressure measuring element) from the interference and impact of dust without increasing the cost.

Please note that the above embodiment is only for an illustrative purpose and is not meant to be a limitation of the present invention. For example, as long as the first electronic element 120 is positioned in a dustproof zone 170 of the chamber structure 110, the positions of the first electronic element 120, the second electronic element 130, and the connecting pad 140 can be changed according to different design requirements. Moreover, if the functions of the second electronic element 130 and the connecting pad 140 can be integrated in other elements of the electronic device 100, the second electronic element 130 and the connecting pad 140 can be omitted in the electronic device 100 in FIG. 1.

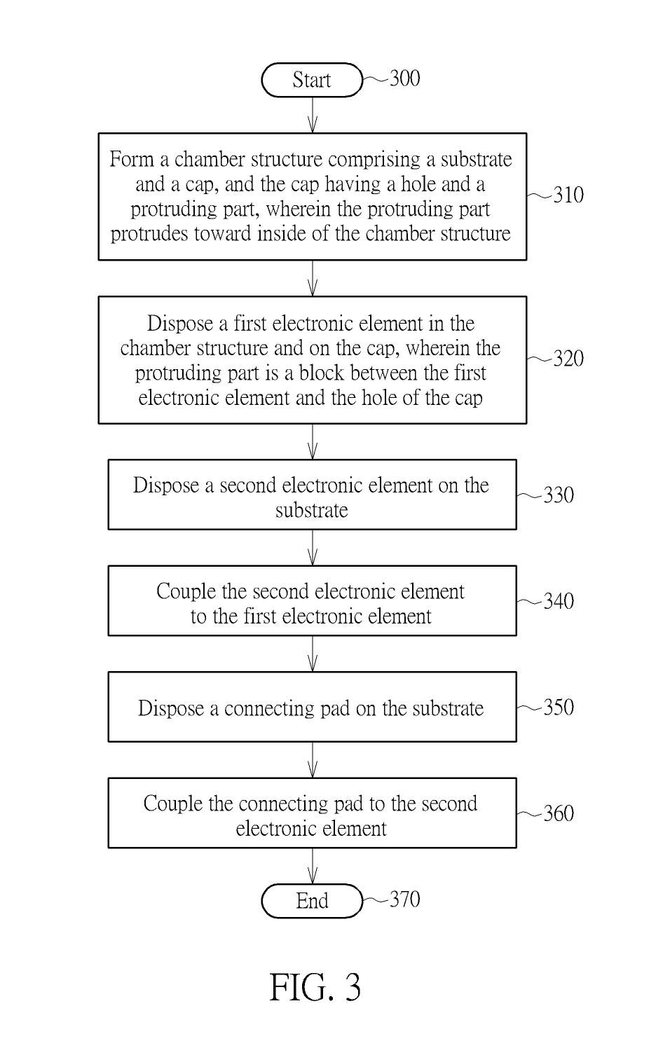

Please refer to FIG. 3. FIG. 3 is a first exemplary flowchart showing a method of fabricating an electronic device with the dust protecting function in accordance with the above electronic device 100 of the present invention. Provided that substantially the same result is achieved, the steps of the process flowchart need not be in the exact order shown in FIG. 3 and need not be contiguous, that is, other steps can be intermediate. The first exemplary method of the present invention comprises the following steps:

Step 300: Start.

Step 310: Form a chamber structure comprising a substrate and a cap, and the cap having a hole and a protruding part, wherein the protruding part protrudes toward inside of the chamber structure.

Step 320: Dispose a first electronic element in the chamber structure and on the substrate, wherein the protruding part is a block between the first electronic element and the hole of the cap.

Step 330: Dispose a second electronic element on the substrate.

Step 340: Couple the second electronic element to the first electronic element.

Step 350: Dispose a connecting pad on the substrate.

Step 360: Couple the connecting pad to the second electronic element.

Step 370: End.

Please note that the above embodiment is only for an illustrative purpose and is not meant to be a limitation of the present invention. For example, if the functions of the second electronic element and the connecting pad can be integrated in other elements of the electronic device 100, the Steps 330-360 can be omitted in the flowchart in FIG. 3.

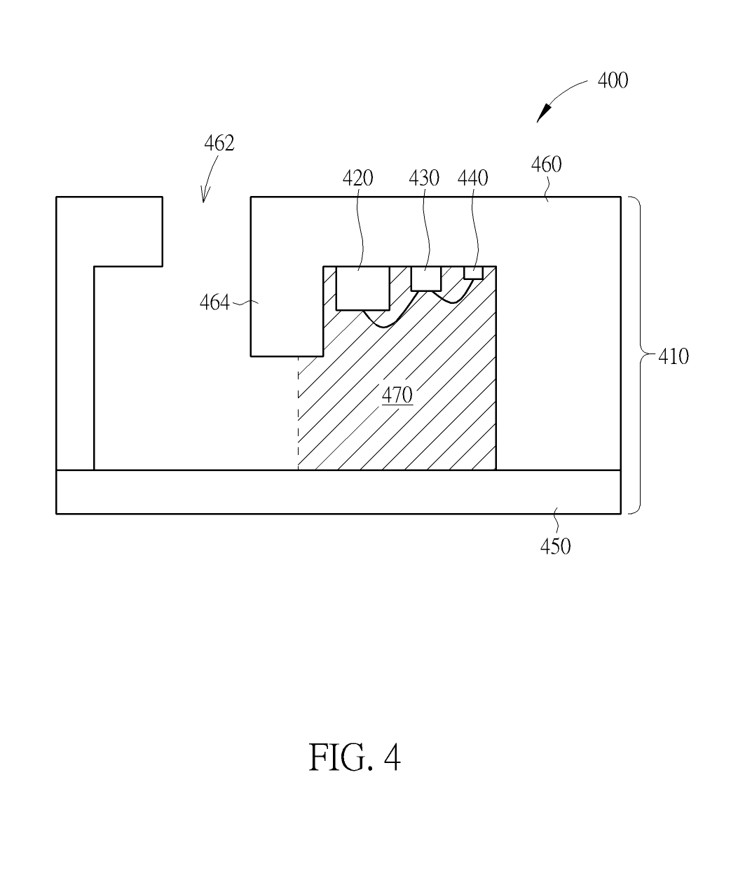

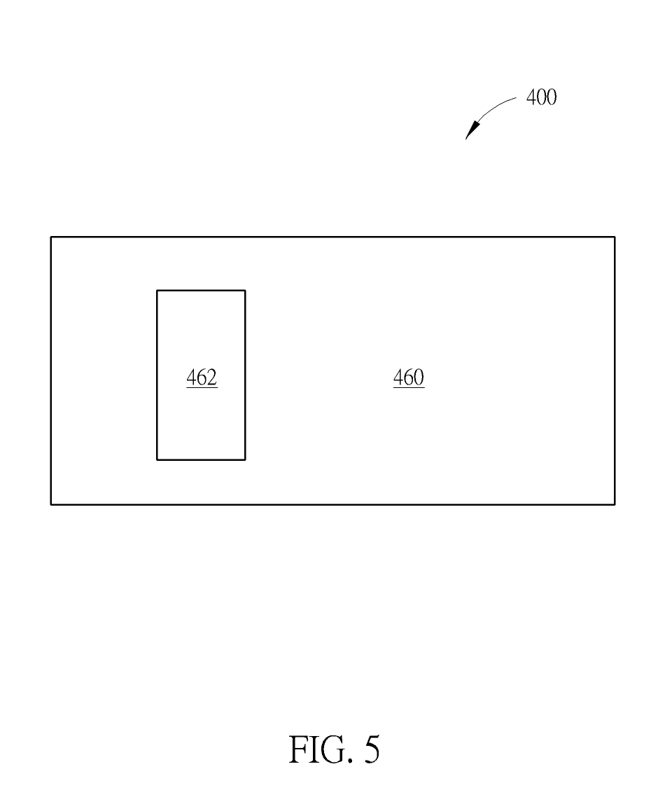

Please refer to FIG. 4 and FIG. 5. FIG. 4 shows a simplified cross-sectional diagram of an electronic device 400 with dust protecting function in accordance with a second embodiment of the present invention, and FIG. 5 shows a simplified top-view diagram of the electronic device 400, wherein the electronic device 400 can be a Micro Electro Mechanical System (MEMS) microphone device or an atmospheric pressure measuring device. The electronic device 400 comprises: a chamber structure 410 a first electronic element 420, a second electronic element 430, and a connecting pad 440, wherein the chamber structure 410 can be a package structure, the first electronic element 420 can be a MEMS microphone element or an atmospheric pressure measuring, and the second electronic element 430 can be an application-specific integrated circuit (ASIC). The chamber structure 410 comprises a substrate 450 and a cap 460, wherein the substrate 450 can be a printed circuit board (PCB) and material of the cap 460 can be metal or plastics. The cap 460 is connected to the substrate 450, and the cap 460 has a hole 462 and a protruding part 464. The present invention can use a etching process to form the hole 462 and the protruding part 464 on the cap 460, wherein the protruding part 464 protrudes toward inside of the chamber structure 410. Please note that the above embodiment is only for an illustrative purpose and is not meant to be a limitation of the present invention. For example, if there are other processes capable of forming the hole 462 and the protruding part 464 under different design requirements, the present invention also can use the other processes to form the hole 462 and the protruding part 464 on the cap 460.

In addition, the first electronic element 420 is disposed in the chamber structure 410 and disposed on the cap 460. The second electronic element 430 is coupled to the first electronic element 420, and disposed in the chamber structure 410 and on the cap 460. The connecting pad 440 is coupled to the second electronic element 430, and disposed in the chamber structure 410 and disposed on the cap 460, wherein the protruding part 464 is a block between the first electronic element 420 and the hole 462 of the cap 460. In this way, the first electronic element 420 is positioned in a dustproof zone 470. Since the present invention can use the etching process to form the hole 462 and the protruding part 464 on the cap 460, the present invention can make the electronic device 400 (such as a MEMS microphone device or an atmospheric pressure measuring device) have dust protecting function to protect the first electronic element 420 (such as a MEMS microphone element or an atmospheric pressure measuring element) from the interference and impact of dust without increasing the cost.

Please note that the above embodiment is only for an illustrative purpose and is not meant to be a limitation of the present invention. For example, as long as the first electronic element 420 is positioned in a dustproof zone 470 of the chamber structure 410, the positions of the first electronic element 420, the second electronic element 430, and the connecting pad 440 can be changed according to different design requirements. Moreover, if the functions of the second electronic element 430 and the connecting pad 440 can be integrated in other elements of the electronic device 400, the second electronic element 430 and the connecting pad 440 can be omitted in the electronic device 400 in FIG. 4.

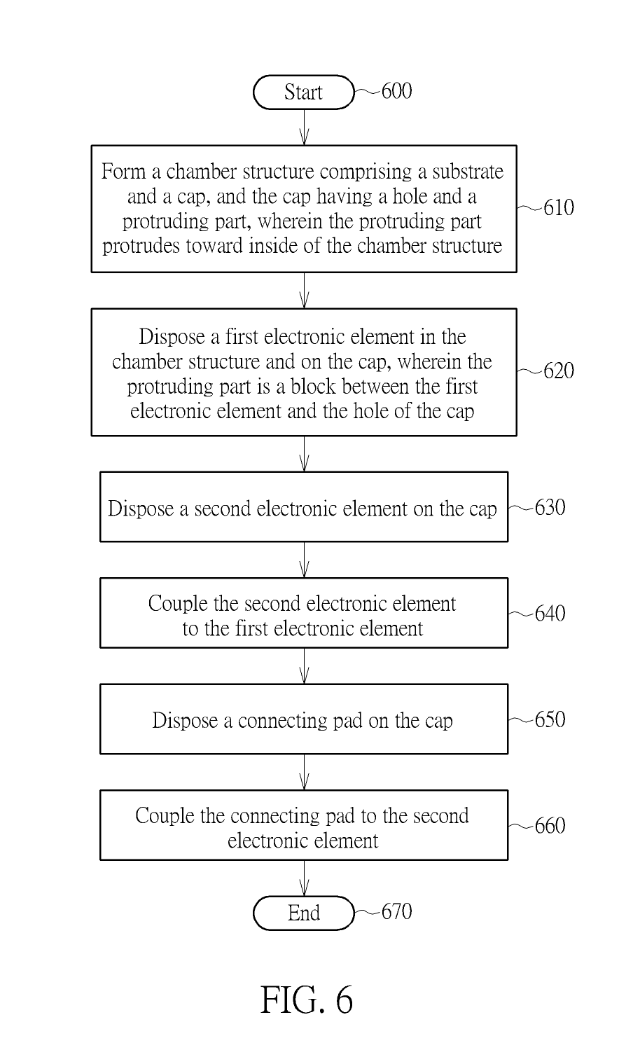

Please refer to FIG. 6. FIG. 6 is a second exemplary flowchart showing a method of fabricating an electronic device with the dust protecting function in accordance with the above electronic device 400 of the present invention. Provided that substantially the same result is achieved, the steps of the process flowchart need not be in the exact order shown in FIG. 6 and need not be contiguous, that is, other steps can be intermediate. The second exemplary method of the present invention comprises the following steps:

Step 600: Start.

Step 610: Form a chamber structure comprising a substrate and a cap, and the cap having a hole and a protruding part, wherein the protruding part protrudes toward inside of the chamber structure.

Step 620: Dispose a first electronic element in the chamber structure and on the cap, wherein the protruding part is a block between the first electronic element and the hole of the cap.

Step 630: Dispose a second electronic element on the cap.

Step 640: Couple the second electronic element to the first electronic element.

Step 650: Dispose a connecting pad on the cap.

Step 660: Couple the connecting pad to the second electronic element.

Step 670: End.

Please note that the above embodiment is only for an illustrative purpose and is not meant to be a limitation of the present invention. For example, if the functions of the second electronic element and the connecting pad can be integrated in other elements of the electronic device 100, the Steps 630-660 can be omitted in the flowchart in FIG. 6.

Briefly summarized, in the electronic device (such as a MEMS microphone device or an atmospheric pressure measuring device) disclosed by the present invention, since the first electronic element (such as a MEMS microphone element or an atmospheric pressure measuring element) is blocked by the protruding part from the hole of the cap (i.e. the first electronic element is positioned in the dustproof zone of the chamber structure), the electronic device disclosed by the present invention can have extremely good dust protecting function to protect the first electronic element from the interference and impact of dust.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electronic device with dust protecting function, comprising:
a chamber structure, comprising:
a substrate; and
a cap, connected to the substrate, having a hole and a protruding part, wherein the protruding part protrudes toward inside of the chamber structure; and
a first electronic element, disposed in the chamber structure, wherein the protruding part is a block between the first electronic element and the hole of the cap.

2. The electronic device of claim 1, further comprising:
a second electronic element, coupled to the first electronic element, wherein the first electronic element and the second electronic element are disposed on the substrate of the chamber structure.

3. The electronic device of claim 1, further comprising:
a second electronic element, coupled to the first electronic element, wherein the first electronic element and the second electronic element are disposed on the cap of the chamber structure.

4. The electronic device of claim 1, wherein the first electronic element is a MEMS microphone element and the electronic device is a MEMS microphone device or an atmospheric pressure measuring device.

5. A method of fabricating an electronic device with dust protecting function, comprising:
forming a chamber structure comprising a substrate and a cap, and the cap having a hole and a protruding part, wherein the protruding part protrudes toward inside of the chamber structure; and
disposing a first electronic element in the chamber structure, wherein the protruding part is a block between the first electronic element and the hole of the cap.

6. The method of claim 5, further comprising:
forming a second electronic element in the chamber structure; and
coupling the second electronic element to the first electronic element.

7. The method of claim 5, wherein the step of disposing the first electronic element in the chamber structure comprises:
disposing a first electronic element on the substrate, wherein the protruding part is a block between the first electronic element and the hole of the cap.

8. The method of claim 5, wherein the step of disposing the first electronic element in the chamber structure comprises:
disposing a first electronic element on the cap, wherein the protruding part is a block between the first electronic element and the hole of the cap.

9. The method of claim 8, further comprising:
forming a second electronic element on the cap; and
coupling the second electronic element to the first electronic element.
